(19) United States
(12) Patent Application Publication
(10) Pub. No.: US 2007/0173082 A1
(43) Pub. Date: Jul. 26, 2007

(54) Embedded connector module

(76) Inventor: Ho-Ming Chiao, Banchiau City (TW)

Correspondence Address: DoTop Technology, Inc., Junghe, P.O. Box No. 6-57, Taipei, 235, TW

(21) Appl. No.: 10/435,463

(22) Filed: May 12, 2003

(51) Int. Cl. H05K 1/00

(52) U.S. Cl. 439/76.1

(57) ABSTRACT

An embedded connector module according to the invention for connecting to video or data storage processing devices includes a housing and a circuit board. The housing is provided with an accommodation room at an interior thereof for embedding and connecting to video or data storage processing device. The circuit board is disposed in the housing, and is provided with inserted connectors for video or data storage processing devices. The circuit board and the housing are assembled as one body, and the connectors disposed at the circuit board are connected to the video and data storage processing device, thereby accomplishing an object of quick installation.

### BACKGROUND OF THE INVENTION

(a) Field of the Invention

The invention relates to an embedded connector module, and more particularly, to an embedded connector module comprising a connector placed in a housing and being readily assembled with or separated from diverse video or data storage processing devices such as CD-ROM, CD-RW, DVD−ROM, DVD-RW, DVD+ROM, MO, and HDD.

(b) Description of the Prior Art

Video or data storage processing devices such as CD-ROM drives, CD burners, hard disks, magneto-optical drives, are classified as internally or externally connected devices. For internally connected installation, a video or data storage processing device is placed at a rear end of a computer host housing, and cables, signal cords, or power lines are inserted at a rear end of the device. For externally connected installation, a video or data storage processing device is placed in to a housing, and cables, signal cords, or power lines similarly exist between the video or data storage processing device and the housing. The externally connected housing is then connected to a computer host via various signal cords such as USB and IEEE1394. However, regardless of the type of conventional video or data storage process devices, because structures of electric connectors and wires thereof are rather fragile, damages and breakage are often incurred during dismounting or assembly thereof. Especially when used items are to be replaced with new items, it is necessary to remove all originally inserted cords in sequence and then connect the connectors to the new items, and thus huge amounts of time and work are wasted. In addition, flexible wires are frequently used for signal transmissions between the storage processing devices and the computer host, hence signals are prone to attenuate due to the wires being easily bent or having poor heat dissipation, and further causing noises and lowering transmission efficiencies as a whole.

### SUMMARY OF THE INVENTION

Therefore, in the view of the aforesaid shortcomings of the prior art as described above, the primary object of the invention is to provided an embedded connector module comprising a connector placed in a housing thereof, and being readily assembled with and dismounted from video or data storage processing devices. Also, the embedded connector in accordance with the invention is simple in operation, time-efficient, and capable providing a more stable signal quality and lowering failure rates thereof.

The secondary object of the invention is to provide an embedded connector module capable of minimizing a volume thereof for saving production materials by modularizing a connector thereof.

### BRIEF DESCRIPTION OF THE DRAWINGS

FIG. 1 shows an exploded elevational view according to the invention.

FIG. 2 shows an elevational view according to the invention.

FIGS. 3 and 4 are schematic views for illustrating the invention being connected with a video or data storage processing device.

### DETAILED DESCRIPTION OF THE PREFERRED EMBODIMENTS

To better understand the characteristics, objects and functions of the invention, detailed descriptions shall be given with the accompanying drawings hereunder.

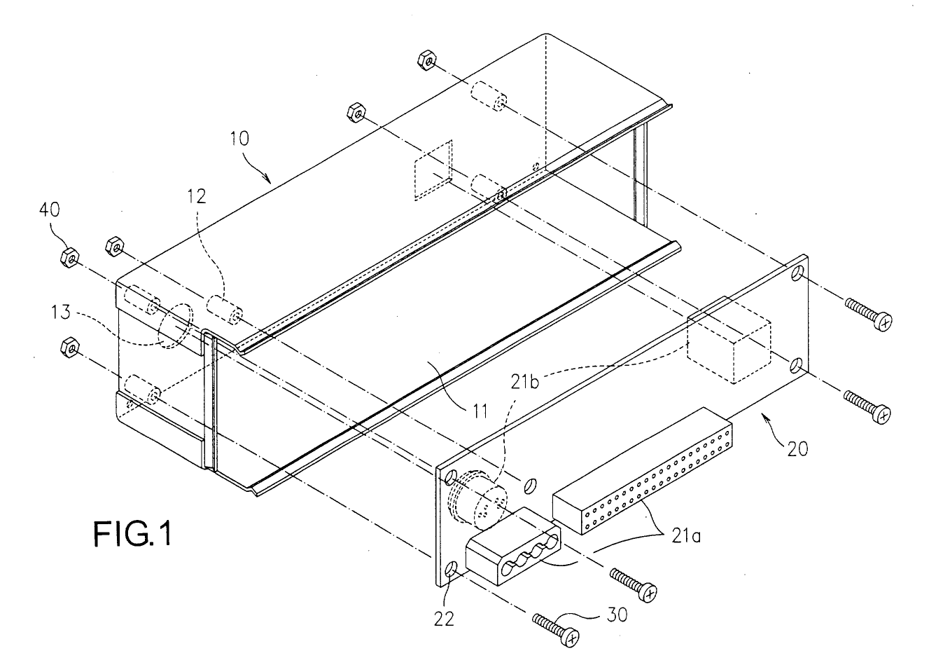

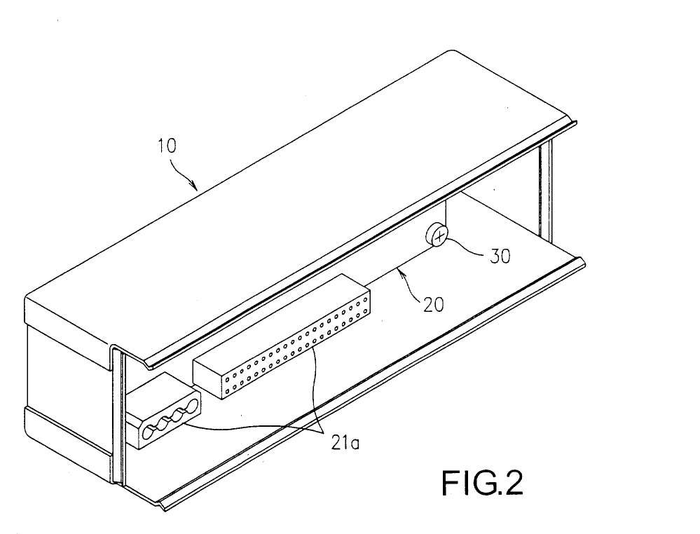

Referring to FIGS. 1 and 2, the embedded connector module according to the invention comprises: a housing 10 in shape of a three-dimensional rectangular body, and being provided with an accommodation room 11 having a plurality of screw pillars 12 at an interior thereof; a circuit board 20 disposed in the aforesaid housing 10, and being provided with inserted connectors for video or data storage processing devices, wherein connectors 21a facing an exterior of the housing 10 serves as signal connectors, power connectors, or cable connectors for connecting to video or data storage processing devices, while connectors 21b disposed at the other side of the circuit board 20 are for connecting to a computer host; and screw openings 22 corresponding to the screw pillars 12 of the housing 10; wherein: the circuit 20 and the housing 10 are screwed and joined using screw bolts 30, and fastened by screw nuts 40; and the housing 10 is provided with an aperture 13 corresponding to the connector 21b for guiding the connector 21b to an exterior to further connect to external connection lines (not shown in the diagram).

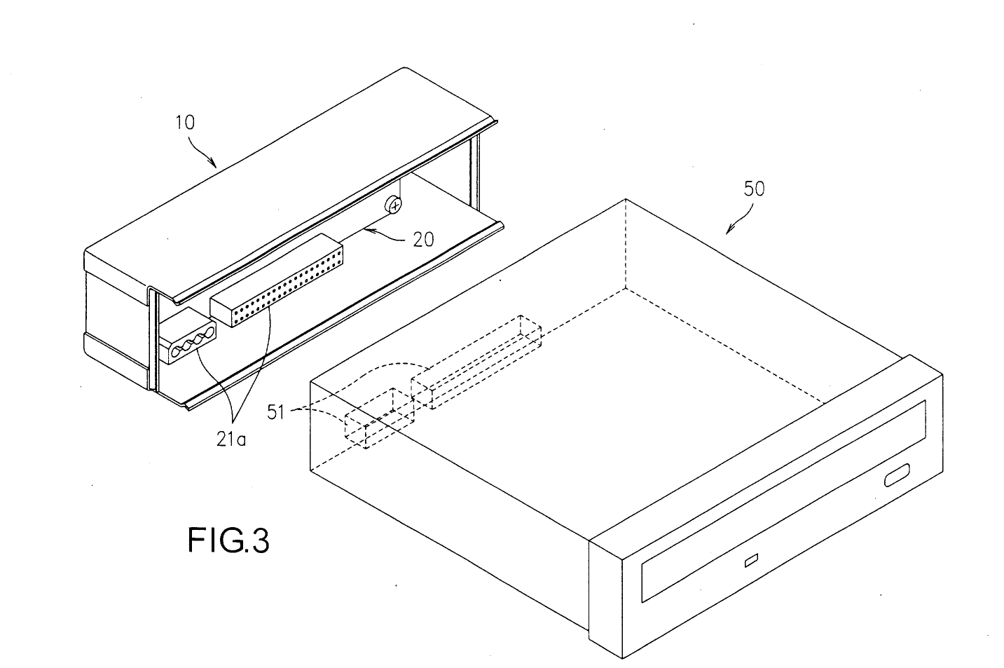

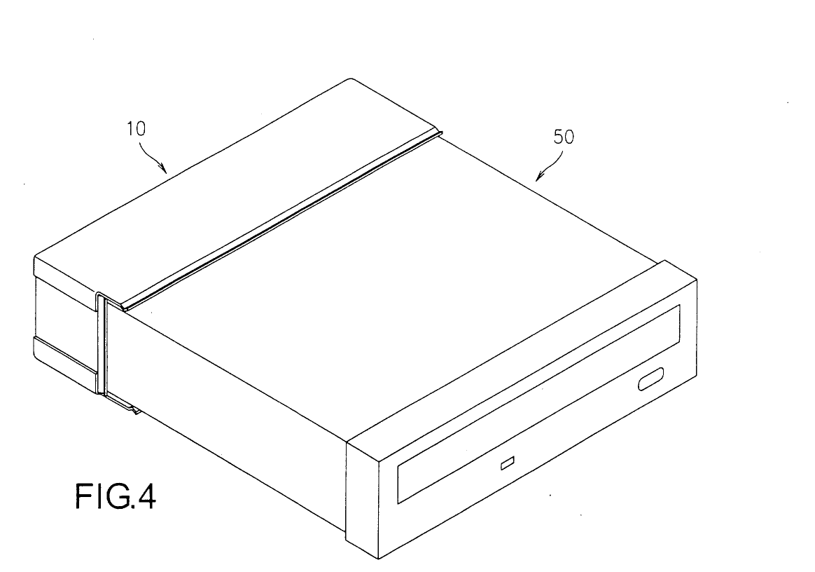

Referring to FIGS. 3 and 4, when the circuit board 20 and the housing 10 are joined as one body, and the housing 10 is embedded at a rear end of a video or data storage processing device 50, the connectors 21a disposed at the circuit board 20 are connected with corresponding insertion openings 51 of the storage processing device 50, thereby assembling the structure according to the invention. The storage processing device 50 may be a video or data storage processing device such as a CD-ROM drive, a CD burner, a hard disk, a magneto-optical drive. To replace the original storage processing device 50 with another storage processing device 50, the circuit board 20 and the storage processing device 50 may be separated by merely extracting the housing 10, and hence it is unnecessary to remove all connection wires one by one. Not only time and work are reduced, but failure rates are also lowered. As a result, the modularized connector in accordance with the invention is capable of minimizing a volume thereof for saving production materials.

It is of course to be understood that the embodiment described herein is merely illustrative of the principles of the invention and that a wide variety of modifications thereto may be effected by persons skilled in the art without departing from the spirit and scope of the invention as set forth in the following claims.

What is claimed is:

1. An embedded connector module for connecting to video or data storage processing devices comprising:
a housing provided with an accommodation room for embedding with a connected video or data storage processing device; and
a circuit board disposed in the housing, and being provided with inserted connectors for video or data storage processing devices;
wherein:
the circuit and the housing are joined as one body, the housing is embedded into the video or data storage device, and the connectors disposed at the circuit are connected to the video or data storage device.

2. The embedded connector module in accordance with claim 1, wherein the housing is a three-dimensional rectangular body in shape, and is provided with an aperture corresponding to the connector disposed at the circuit board for connecting to the connector.

3. The embedded connector module in accordance with claim 1, wherein the housing is provided with a plurality of screw pillars at an interior thereof, and the circuit board is disposed with screw openings corresponding to the screw pillars, thereby screwing and joining the circuit board and the housing using screw bolts.

4. The embedded connector module in accordance with claim 1, wherein the connectors disposed at the circuit board include signal cord connectors, cable connectors, power connectors and sockets.
